(19) United States
(12) Patent Application Publication
(10) Pub. No.: US 2004/0040503 A1
(43) Pub. Date: Mar. 4, 2004

(54) Micromachines for delivering precursors and gases for film deposition

(75) Inventors: Cem Basceri, Boise, ID (US); Gurtej S. Sandhu, Boise, ID (US)

Correspondence Address: HOWREY SIMON ARNOLD & WHITE LLP, 750 BERING DRIVE, HOUSTON, TX, 77057, US

(73) Assignee: Micron Technology, Inc.

(21) Appl. No.: 10/330,516

(22) Filed: Dec. 27, 2002

Related U.S. Application Data
(63) Continuation-in-part of application No. 10/230,874, filed on Aug. 29, 2002.

(51) Int. Cl. C23C 16/00

(52) U.S. Cl. 118/715

(57) ABSTRACT

An improved gas precursor delivery system for a deposition chamber is disclosed. The system includes, in a preferred embodiment, a shower head containing holes through which the gas precursors will be delivered to the deposition chamber. Each hole within the shower head has associated with it a flow regulating micromachine, such as a microvalve or micropump, for independently regulating the flow of the precursor into the deposition chamber, and if necessary, for vaporizing the source chemical. Each micromachine is preferably associated with a single precursor source, and hence precursor lines are not shared and thus do not need to be purged with the introduction of each new precursor, saving manufacturing time and decreasing wasted precursor gas. Precise control of precursors into the chamber via the micromachines allows film stochiometry and thickness to be carefully controlled.

### CROSS-REFERENCE TO RELATED APPLICATIONS

This application is related to “Reactors Having Gas Distributors and Methods for Depositing Materials Onto Micro-device Workpieces,” filed Aug. 23, 2002 (Micron Docket 01-1047), filed in the name of Cem Basceri and Gurtej S. Sandhu, and which is incorporated herein by reference. This application is also a continuation-in-part of U.S. patent application Ser. No. 10/230,874, filed Aug. 29, 2002, to which priority is claimed under 35 U.S.C. § 120, and which is also incorporated herein by reference.

### FIELD OF THE INVENTION

This invention relates generally to methods and apparatuses for delivering precursor gases into a deposition chamber of the type typically used in the processing of substrates for microelectronics.

### BACKGROUND OF THE INVENTION

Some of the various layers in a traditionally-manufactured integrated circuit are formed by deposition, and more specifically by chemical vapor deposition (CVD). In a typical deposition process, a substrate is situated in a deposition chamber and the gas precursors that are used to form the deposited layer are introduced into the chamber. (As used herein, the term “substrate” should be understood to encompass any work piece capable of receiving a deposited film, and is typically a semiconductor wafer in either its natural or partially manufactured state having other layers previously formed thereon, or an alumina, zirconia, or titanate ceramic work piece). The gas precursors may then react in the chamber and the by-products of this reaction eventually find their way onto the surface of the substrate to form the layer of interest. For example, if it were desirable to form a titanium nitride (TiN) layer on the surface of the substrate, precursor gases of TiCl₄ and NH₃ could be used. Varying the heat and pressure inside the chamber, or at the surface of the substrate, can help to facilitate the deposition process as is well known.

While some of the source chemicals in a deposition process naturally occur in a gas state, other chemicals naturally occur in a liquid state. Such liquid chemicals must first be converted to a gaseous state before being suitably utilized in a CVD process, i.e., they must be vaporized. As is well known, such vaporization can occur either by modifying either the temperature or the pressure of the chemical at issue relative to its surroundings. In the example given above for example, TiCl₄ must first be vaporized before being suitable for use in a CVD process, although NH₃, which is gaseous, can be used without further modification.

A typical deposition chamber 8 is shown in FIGS. 1A and 1B, and comprises a wall 10 and a substrate chuck (or support) 12 for holding the substrate 14 onto which the film will be deposited. Also shown is a “shower head” 16, which is an industry standard means for conveying the precursor deposition gases 18 to the chamber 8. The shower head 16 is typically approximately the same size as the substrate 14, and contains holes 17 to attempt to evenly distribute the precursor gases into the chamber 8, as is best seen in the underside view of FIG. 1B. The precursor gases 18 are sent to the shower head 16 by a conduit 20, which is turn is connected to the various chemical sources 22. Although not shown, the conduit 20 in the shower head 16 may constitute more narrow channels formed within the bulk of the shower head material, whereby the channels are connected together and ultimately exit at holes 17.

Continuing with the above example, separate sources 22 for the TiCl₄ and NH₃ are coupled to the conduit 20, although the liquid TiCl₄ source 22 must first pass through a vaporizer 24, a well known structure in the semiconductor processing arts. The shower head 16 and associated conduit 20 are typically formed of aluminum, although one skilled in the art will recognize that the material to be chosen for these structures depends on the chemicals with which they will be used. Further information regarding shower head designs, and deposition chambers more generally, may be found in U.S. Pat. Nos. 6,210,754, 6,182,603, and 6,290,491, which are hereby incorporated by reference in their entireties.

Of course, FIG. 1 is simplified for clarity and contains many other structures in an actual commercial embodiment as one skilled in the art will recognize. For example, the substrate chuck 12 might contain a heating or cooling element, as might the chamber 8 and/or the other structures involved in deposition of the precursor gases. Also, many other sources 22 may be connected to conduit 20, depending on the deposition to be performed. Additionally, a typical commercial system may include various valves, pumps, or flow rate controllers designed to control the amount or combination of precursor gases flowing into the conduit 20, or to control the time or times at which such gases flow during the deposition process. Additionally, a typical commercial system might also include a pump for purging the chamber or conduit of spent or unwanted precursor gases. A purging source, typically containing an inert gas such as Argon, may also be connected to conduit 20 to assist in purging the chamber of the precursor gases.

Purging the chamber is often necessary at the end of the deposition process, but also can take place during a deposition process if the precursor gases are changed in the middle of the deposition. Such in-situ purging is often necessary during well-known atomic layer deposition (ALD) processes, where a first precursor (or precursor combination) is introduced to form a very thin sub-layer on the substrate, followed by a second precursor (or precursor combination) to form a second very thin sub-layer on the first, followed by another iteration of the first precursor, and so on, to build a single film constructed at the atomic or near-atomic layer of alternating sub-layers. ALD films can be used to form amorphous layers, or may be used to form crystalline layers if deposited on a crystalline substrate in an epitaxial fashion. While ALD films often exhibit desirable properties, the failure to purge between changing the precursor gases can lead to impurities or discontinuities in the films so formed.

Prior art precursor delivery systems such as those just described suffer from certain drawbacks.

First, films deposited by traditional CVD techniques may not be formed of uniform thickness throughout the radius of the substrate, which can occur due to a phenomenon known as the “jetting effect.” The jetting effect occurs because of the configuration of the conduit 20 and the shower head 16. Because holes 17 in the shower head 16 that are closer to the conduit 20, i.e., those holes in the center of the shower head 16, such as hole 17a, will pass the precursor gases from the conduit 20 with less resistance, the concentration of precursor gases will be higher in the center of the substrate 14 than at locations peripheral to the substrate, such as at hole 17b. This results in the deposited film being thicker in the center of the substrate 14, which is generally not desirable.

Second, traditional CVD techniques can be inefficient, expensive, and time consuming, particularly when forming ALD films. The precursor gases must pass through the conduit 20 before emerging out of the shower head 16 to the chamber 8 where they are useful. Gas left remaining in the conduit 20 must usually be purged after a deposition process, or in the middle of certain deposition processes. This process takes time to perform, and to a certain degree is wasteful of the precursor gases. In the ALD process described above, the necessity of purging the conduit 20 each time the source gas is changed during the formation of the sub-layers can significantly increase the time of the process and limit its throughput, creating a bottleneck in the manufacturing process. This is especially true if several precursor gas changes need to be made during the process. These delays are exacerbated if vaporization of the source chemicals needs to be performed, a process which itself takes time.

Third, for gases that require multiple precursor gases to be presented simultaneously to the substrate 14, the traditional CVD technique can be difficult to adequately control. A good example of such difficulties are encountered in the formation of a BST (barium-strontium-titanium) oxide dielectric, which may involve precursor source gases of Ba(thd)₂-tetraglyme (barium bis-tetramethylheptanedionate tetraglyme), Sr(thd)₂-tetraglyme (strontium bis-tetramethylheptanedionate tetraglyme), and Ti(OPri)₄ (titanium isopropoxide). BST oxide dielectrics are desirable for use in integrated circuitry because they exhibit high dielectric constants, which make them particularly well-suited for the formation of thin capacitors needing high capacitances, e.g., the capacitors in a Dynamic-Random-Access-Memory (DRAM) memory cell. To achieve proper film stochiometry and hence proper capacitance, it is important that the correct amounts of the BST oxide precursor gases flow into the chamber 8. While flow meters may be used to regulate the flow of these precursor gases into the conduit, their relative proportions may become difficult to control once they enter into and mix within the conduit 20 and the shower head 16, with the result being that the desired amounts are not presented to the chamber 8, or at the exact proper times. Indeed, it may be necessary to run the precursor gases for some time before beginning the actual deposition process to ensure that the correct proportions are present within chamber 8, which is wasteful and time consuming. Furthermore, depending on the deposition process at hand, the simultaneous presentation of the precursor gases into conduit 20 and shower head 16 may cause unwanted reactions between the precursor gases to occur in those areas. If so, the useful reactivity of the precursor gases is negatively impacted or diluted, and the conduit 20 and shower head 16 may become contaminated with or degraded by the by-products of these unwanted reactions. Accordingly, the conduit 20 and/or shower head 16 may need to be periodically cleaned or changed, adding further expense and downtime to the deposition process.

A solution to these undesirable effects would be beneficial, and is presented herein.

### SUMMARY OF THE INVENTION

An improved gas precursor delivery system for a deposition chamber is disclosed. The system includes, in a preferred embodiment, a shower head containing holes through which the gas precursors will be delivered to the deposition chamber. Each hole within the shower head has associated with it a flow regulating micromachine, such as a microvalve or micropump, for independently regulating the flow of the precursor into the deposition chamber, and if necessary, for vaporizing the source chemical. Each micromachine is preferably associated with a single precursor source, and hence precursor lines are not shared and thus do not need to be purged with the introduction of each new precursor, saving manufacturing time and decreasing wasted precursor gas. Precise control of precursors into the chamber via the micromachines allows film stochiometry and thickness to be carefully controlled.

### BRIEF DESCRIPTION OF THE DRAWINGS

The foregoing and other features and aspects of the present invention will be best understood with reference to the following detailed description of specific embodiments of the invention, when read in conjunction with the accompanying drawings, wherein:

FIG. 1A shows a prior art deposition system with a prior art gas precursor delivery system.

FIG. 1B shows an underside view of the shower head disclosed in FIG. 1A.

FIG. 2A shows an embodiment of an inventive gas precursor delivery system incorporated into a deposition chamber.

FIG. 2B shows an underside view of the shower head of the embodiment of FIG. 2A.

FIG. 2C shows an underside view of a showed head having a circularly symmetric distribution of holes.

FIG. 3 shows an exemplary micromachine incorporatable into the shower head design of the present invention.

FIG. 4 shows an embodiment of an inventive gas precursor delivery system incorporated into a deposition chamber for the exemplary purpose of depositing BST oxides.

As one skilled in the art will recognize, the Figures are not necessarily drawn to scale.

### DETAILED DESCRIPTION OF EMBODIMENTS OF THE INVENTION

In the disclosure that follows, in the interest of clarity, not all features of actual implementations are described in this disclosure. It will of course be appreciated that in the development of any such actual implementation of the disclosed invention, as in any such project, numerous engineering and design decisions must be made to achieve the developers' specific goals, e.g., compliance with mechanical and business related constraints, which will vary from one implementation to another. While attention must necessarily be paid to proper engineering and design practices for the environment in question, it should be appreciated that such a development effort would nevertheless be a routine undertaking for those of skill in the art given the details provided by this disclosure, even if such development efforts are complex and time-consuming.

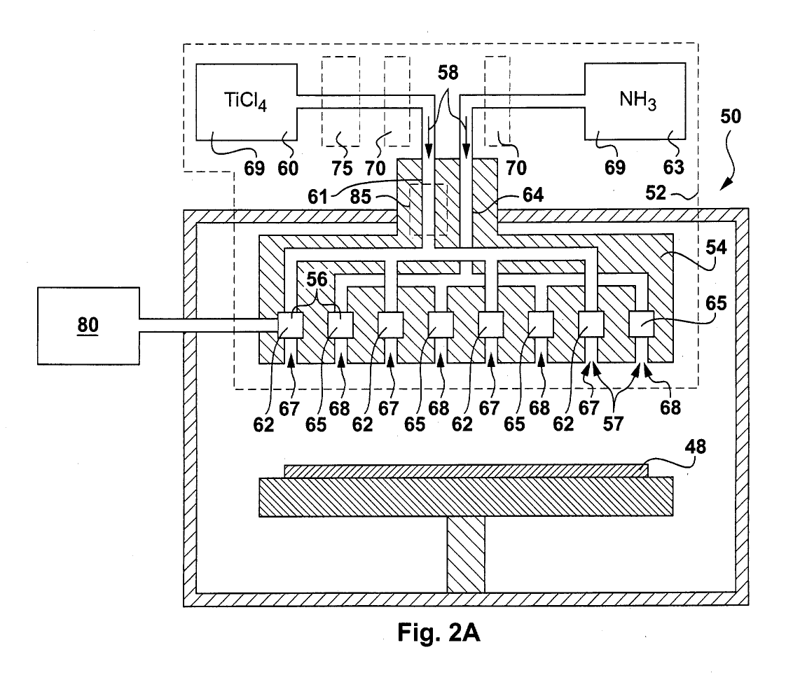

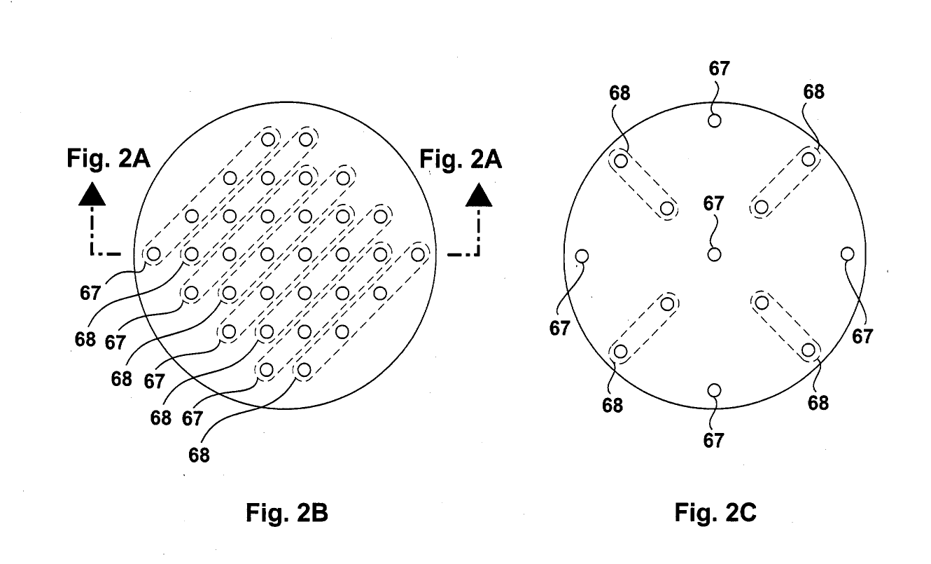

An embodiment of the present invention is illustrated in FIGS. 2A and 2B, which shows a gas precursor delivery system 52 incorporated into an otherwise standard deposition chamber 50. The gas precursor delivery system 52 includes a shower head 54 which has been modified to incorporate several micromachines 56 for delivering precursor gases directly into the deposition chamber. In a preferred embodiment, the micromachines 56 should be understood to include micropumps, microvalves or mass flow controllers, as will be described in particular embodiments later in this disclosure, although one skilled in the art will recognize that other types of micromachines 56 are possible which will function or could be made to function to realize the benefits of this disclosure.

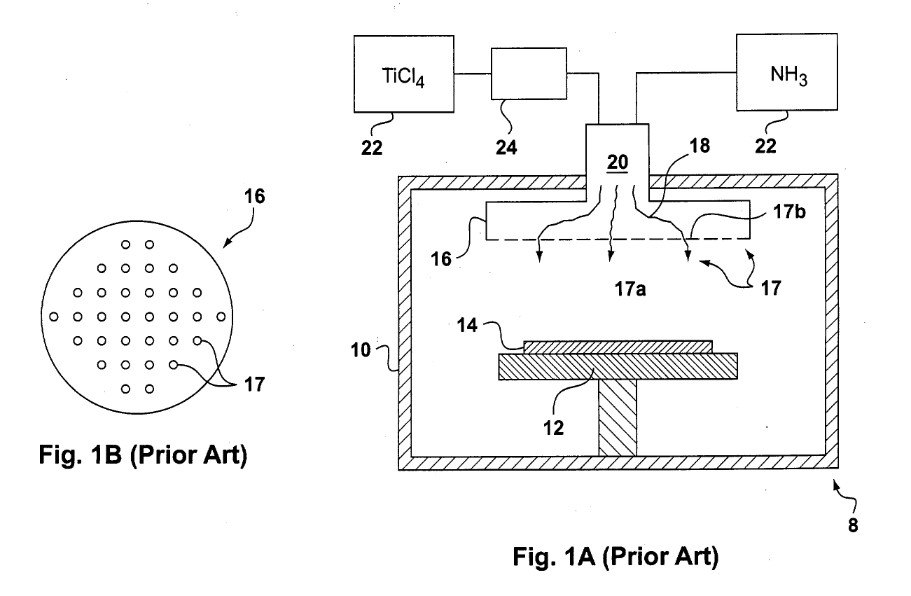

Each of the micromachines 56 is in communication with a particular hole 57 in the shower head 54, and generally functions to control the delivery of the precursor gases into the chamber 50 in precise quantities and at the correct times during the deposition process. The other side of the micromachines 56 are in communication with the precursor gas sources 69. From this configuration, it will be appreciated that each of the gas sources 69 shares a dedicated line 58 to dedicated holes 57 in the shower head 54. In other words, the gas precursors do not share a common conduit (such as conduit 20 as described above with respect to the prior art in FIG. 1) for delivery through the shower head. Thus, in the example shown in FIG. 2A, which shows an exemplary configuration for the deposition of titanium nitride films, the TiCl₄ source 60 has a dedicated line 61 to its dedicated micromachines 62 and holes 67, and the NH₃ source 63 has a dedicated line 64 to its dedicated micromachines 65 and holes 68. As best shown in FIG. 2B, the source-dedicated holes 67, 68 are preferably evenly dispersed throughout the circular area that defines the underside of the shower head 54 to ensure that the precursors gases are evenly distributed in the chamber and vis-à-vis the wafer 48. However, the source-dedicated holes 67, 68 could be distributed in other arrangements (i.e., triangular, checkerboard pattern, etc.) designed to benefit the particular process at hand, or could be distributed unevenly to distribute gases non-uniformly in particular areas of the wafer if desired. Furthermore, more than two precursors gases, each with their own source-dedicated holes, could be used. Of course, the number of holes 57, and their spacing on the shower head 54, can be easily varied. FIG. 2C shows another embodiment wherein the holes 67, 68 are arranged in a more circularly symmetrical arrangement. In this embodiment, vapor delivery might be made to appear at holes 67, while holes 68 distribute other gases or vapors. The disclosed embodiments should only be understood as an exemplary way of distributing the holes to evenly distribute the precursor gases.

One skilled in the art will recognize that manufacture of the shower head 54 of FIG. 2A is easily accomplished, and lends itself to the way that showerheads are normally constructed in the prior art. The shower head 54 could be formed of one uniform piece containing the necessary channels therein. However, it may be easier for a given application to form the shower head 54 as a series of stacked and bolted plates (not shown), each containing the necessary channeling and through-holes necessary to arrive at the channeled structure shown. In this regard, a special plate in this stacked structure could be used for housing the micromachines 56, and would contain small conduits to allow wires to reach between the micromachines and a micromachine controller 80 (shown for simplicity as being connected to only a single micromachine 56). Such controllers 80, i.e., of the kind useable to control valves, pumps, and flow controllers, are well known in the art. The controller 80 in a preferred embodiment constitutes a portion of a larger computerized controller that would be used to control other aspects of the deposition chamber 50 as well as opening and closing of the micromachines 56, such as heat and pressure regulation, control of vaporizers and flow controllers (if any), etc.

Alternatively, the shower head 54 could be essentially hollow in nature with the micromachines 56 mounted to the bottom plate of the shower head. The interior ends of the micromachines in this embodiment could be connected by hoses (similar in function to the channels shown in FIG. 2A), such as metallic or Teflon hoses, which in turn are connected to the various sources 69. In a preferred embodiment, the hoses coming from each source would branch into smaller hoses which meet with the corresponding micromachines. Again, the wires connecting the micromachines 56 to the controller 80 can be made to pass through a suitable port on the side on the shower head 54. One skilled in the art will recognize that other constructions for the delivery system 52 are possible, and that the materials to be used for each component of the delivery system 52 will necessarily be determined in accordance with the chemicals and precursor gases to be used to ensure that corrosion of these materials are minimized.

The gas precursor delivery system 52 of FIG. 2A eliminates many of the above-mentioned shortcomings of the prior art, including the need to purge the conduit and the needless waste of precursor gases. As a result, time savings can be realized, particularly in ALD processes, resulting in increased manufacturing throughput. Moreover, because each hole 57 is, in a preferred embodiment, independently controlled by its own micromachine, the flow rate of the precursor gas through each hole 57 can be precisely controlled so as to eliminate the unwanted non-uniformities of the jetting effect discussed earlier. Furthermore, because each of the lines (e.g., 61 or 64) are preferably (although not necessarily) dedicated to use with a particular precursor chemical, these lines may be specially constructed to handle that chemical to minimize corrosive effects or otherwise to minimize the amount of maintenance that would be necessary for the lines.

Other embodiments which realize these same beneficial effects are easily recognizable by those of skill in the deposition arts. For example, it may not be necessary in all applications to independently control the micromachines 56 occurring at each hole 57 in the shower head 54. Instead, it may be sufficient to control all of the source dedicated micromachines (e.g. 62 or 65) with a single controller to engage those micromachines in unison instead of individually. Furthermore, optional mass flow controllers 70 can be used to control the exact amount of precursor flowing through a particular line 58, although this modification may result in unnecessary expense for a given application. One could also dispense with a discrete shower head 54 altogether, and instead have the gases ported directly into the top of the chamber 50 through micromachines incorporated on, or within, the chamber.

Other useful structures, such as those already known in the prior art and recognized by those of skill, can be incorporated with the disclosed gas delivery system as well. For example, while not necessarily required in a given application, additional holes 57 could be provided in the shower head 54 which are connected to a purging source, such as Argon, for purging the chamber. Additionally, the purging source could be connected to the lines 61 and 64 to purge them if necessary or helpful for a given application. Furthermore, two or more precursors could be communicated to any given micromachine or its associated line, should this be necessary or helpful for a given deposition process.

Micromachines 56 are well known and encompass various structures, such as those disclosed in the following references, which are incorporated herein by reference in their entireties: U.S. Pat. No. 5,865,417, entitled “Integrated Electrically Operable Normally Closed Valve,” issued Feb. 2, 1999 in the name of Harris et al.; U.S. Pat. No. 6,129,331, entitled “Low-Power Thermopneumatic Microvalve,” issued Oct. 10, 2000 in the name of Henning et al.; U.S. Pat. No. 4,966,646, entitled “Method of Making an Integrated, Microminiature Electric-to-Fluidic Valve and Pressure/Flow Regulator,” issued Oct. 30, 1990 in the name of Zdeblick; U.S. Pat. No. 5,865,417, entitled “Integrated Electrically Operable Normally Closed Valve,” issued Feb. 2, 1999 in the name of J. M. Harris et al; U.S. Pat. No. 6,123,107, entitled “Apparatus and method for mounting micromechanical fluid control components,” issued Sep. 26, 2000 in the name of M. Selser et al.; U.S. Pat. No. 6,129,331, entitled “Low-power Thermopneumatic Microvalve,” issued on Oct. 10, 2000 in the name of A. K. Henning et al.; U.S. Pat. No. 6,149,123, entitled “Integrated Electrically Operable Micro-Valve,” issued Nov. 21, 2000 in the name of J. M. Harris et al.; A. K. Henning et al., “A Thermopneumatically Actuated Microvalve for Liquid Expansion and Proportional Control,” Proceedings: Transducers '97: 1997 International Solid State Sensors and Actuators Conference, pp. 825-28 (IEEE Press, Piscataway, N.J., 1997); A. K. Henning et al, “Microfluidic MEMS for Semiconductor Processing,” IEEE Transactions on Components, Packaging, and Manufacturing Technology B21, pp. 329-37 (1998); A. K. Henning, “Microfluidic MEMS,” Proceedings: IEEE Aerospace Conference, Paper 4.906 (IEEE Press, Piscataway, N.J., 1998); J. S. Fitch et al., “Pressure-Based Mass-Flow Control Using Thermopneumatically-Actuated Microvalves,” Proceedings: Solid-State Sensor and Actuator Workshop, pp. 162-65 (Transducers Research Foundation, Cleveland, Ohio, 1998); A. K. Henning et al, “Performance of MEMS-Based Gas Distribution and Control Systems for Semiconductor Processing,” Proceedings: SEMICON West Workshop on Gas Distribution (SEMI, Mountain View, Calif., 1998); A. K. Henning et al., “Contamination Reduction Using MEMS-Based, High-Precision Mass Flow Controllers,” Proceedings: SEMICON West Symposium on Contamination Free Manufacturing for Semiconductor Processing (SEMI, Mountain View, Calif., 1998); A. K. Henning, “Liquid and Gas-Liquid Phase Behavior in Thermopneumatically Actuated Microvalves,” Proceedings: Micro Fluidic Devices and Systems, Vol. 3515, pp. 53-63 (International Society for Optical Engineering, Bellingham, Wash., 1998); A. K. Henning et al., “Performance of MEMS-Based Gas Distribution and Control Systems for Semiconductor Processing,” Proceedings: Micromachined Devices and Components, Vol. 3514, pp. 159-170 (International Society for Optical Engineering, Bellingham, Wash., 1998); D. Maillefer et al., “A High-Performance Silicon Micropump for Disposable Drug Delivery Systems,” Proceedings of the MEMS 2001 Conference, Interlaken Switzerland, pp. 413-17 (2001); P. Woias, “Micropumps—Summarizing the First Two Decades,” Proceedings: SPIE—International Society for Optical Engineering, Vol. 4560, pp. 39-52 (2001); R. Bardell et al., “Designing High-Performance Micro-Pumps Based On No-Moving-Parts Valves,” ASME—Microelectromechanical Systems (MEMS), DSC-Vol. 62 HTD-Vol. 354, pp. 47-53 (1997); and A. Olsson, “Valve-Less Diffuser Micropumps” (1998), published at http://www.s3.kth.se/mst/research/dissertations/pdf/andersodoc.pdf. As one skilled in the art will appreciate, many of the micromachines in the foregoing incorporated references could be incorporated into a shower head to achieve the benefits of the present disclosure.

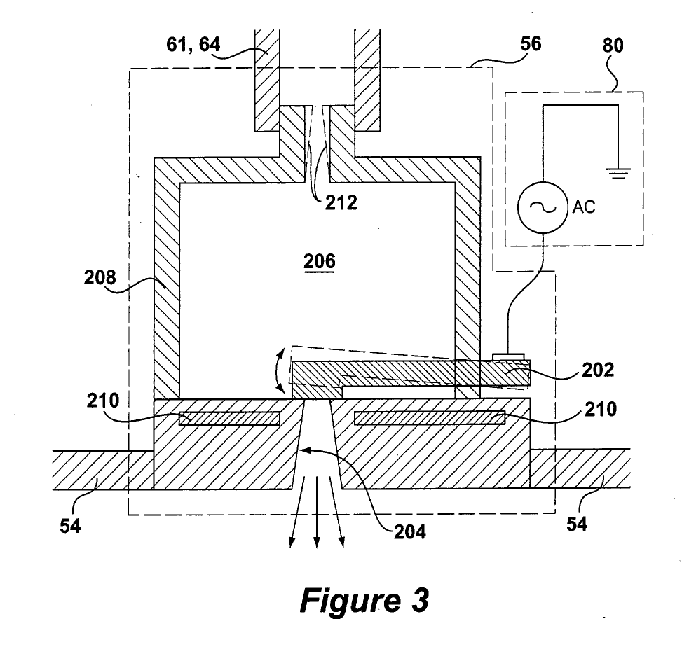

FIG. 3 shows one such suitable micromachine 56, more particularly a microvalve, suitable for use with the present disclosure. The microvalve 56 includes a piezoelectric actuator 202 which normally covers an output nozzle 204 formed in the housing of the microvalve. When stimulated by an AC voltage (preferably incorporated into the micromachine controller 80), the actuator 202 will bend, thus, exposing the source chemical 206 within cell 208 to the output nozzle 204 and ultimately out into the chamber where the chemical can be used in a deposition process. As one skilled in the art will appreciate, the frequency and/or the duty cycle of the AC signal will determine the flow rate of the source chemical 206, and these AC parameters may be easily varied to accommodate a given deposition process. While the signal applied to the actuator 202 can be truly varying, i.e., opening and closing the nozzle 204 in a cyclic pattern, the signal may also be used to pulse open the actuator for a set time.

When the source chemical 206 is a gas, like NH₃, the physics of releasing the source gas through the nozzle is relatively easy to control. When the source chemical 206 is a liquid, care must be taken to vaporize the source chemical prior to its release into the chamber. However, vaporization of liquid sources is easily handled in a number of different ways. First, given that depositions chambers are usually held at relatively low pressures, the pressure of the source chemical 206 in cell 208 can be adjusted to ensure that the source chemical will vaporize when exposed by the actuator 202. In this regard, it may be necessary to engineer the shape or diameter of the output nozzle 204 to ensure that a sufficient pressure differential exists to promote vaporization. Vaporization may be facilitated or controlled in other ways. For example, a resistive heating layer or element 210 may be incorporated into the microvalve 56 to control the temperature of the source chemical 206 within the cell 208 to assist in its vaporization upon release of the actuator 202. This heating layer is preferably also connected to and controlled by the micromachine controller 80. Additionally, the heat residing within the deposition chamber may be sufficient to promote vaporization without the need to specifically heat the source chemical 206.

Additional control of the source chemical may be promoted by tapering the input nozzle 212 of the microvalve 56. For example, by tapering the input nozzle 212 (shown in phantom in FIG. 3) the source chemical can be engineered to act as essentially a one-way valve that will allow fluid to flow into the cell 108 from source lines 61, 64, but not substantially in the reverse direction. Optionally, another piezoelectric actuator (not shown) could be present at in the input nozzle 212 to further control fluid input into the micromachine 56. Finally, in some applications where it might be worrisome that liquid source chemicals will spill out of the microvalve in an unvolatized form, the micromachine could be turned upside down within the shower head 54 with the output nozzle appropriately re-directed out of the bottom of the shower head 54.

In an alternative micromachine design employable in the disclosed shower head design, the micromachine 56 could employ a flexible wall or baffle connected to a piezoelectric disk in communication with the source chemical cell 208, such as is disclosed in A. Olsson, “Valve-Less Diffuser Micropumps,” published at http://www.s3.kth.se/mst/research/dissertations /pdf/andersodoc.pdf, Section 5.2.2. Another valve suitable without substantial modification is disclosed in U.S. patent application Ser. No. 09/651,037, entitled “Method and Apparatus for Pressure Regulation Using Piezoelectric Valve,” filed Aug. 30, 2000, which is incorporated herein by reference in its entirety. The micromachine could comprise a thermopneumatic microvalve such as that disclosed in U.S. Pat. No. 6,129,331. Other micromachines could also be employed, such as those manufactured by Redwood Microsystems of Menlo Park Calif., including the MEMS-Flow™ Gas MFC, the MEMS-Flow™ IGS-MFC, the MEMS-Flow™ 100:1 MFC, the μFR+™ flow regulator, the NC-1500 Fluistor™ microvalve, or the μPR+™ pressure regulator, all of which are described at http://www.redwoodmicro.com/products.htm and which are incorporated by reference herein.

Many other types of microvalves or micropumps could be incorporated into the disclosed showerhead design, such as peristaltic, reciprocating, or rotary pumps. Moreover, the disclosed microvalve design can be manufactured in a number of different ways, including by micromachining, semiconductor process, or thermoplastic techniques, and suitable techniques for such fabrication are disclosed in the incorporated references. Care should be taken when choosing the materials for the micropumps to ensure that they will not be corroded by the source chemicals. In this regard, appropriate coating of certain components may be required. In a preferred embodiment, the size of the micromachine 56 should be approximately 1-5 centimeters cubed to ensure that a sufficient number of micromachines, and their associated cabling, can be coupled onto the plate of the shower head 54.

Depending upon the micromachine design to be employed, it should be appreciated that the design of the gas delivery system of FIG. 2 not only realizes the benefits noted above, but also allows vaporizers to be eliminated from the system. However, it is also possible to use the disclosed invention in conjunction with the use of vaporizers. Accordingly, a traditional vaporizer 75 could be introduced into the delivery system 52 in the line 61 for the TiCl₄ source if necessary or beneficial.

The disclosed gas precursor delivery system of FIG. 2 can be used to deposit a titanium nitride layer in either an ALD or a non-ALD process. In a non-ALD process, TiCl₄ (titanium tetrachloride) and NH₃ (anhydrous ammonia) can be introduced into chamber 50, which is preferably held at a pressure of approximately 10 torr and a temperature of approximately 600° C. Employing a TiCl₄ flow rate of approximately 400 sccm and an NH₃ flow rate of approximately 100 seem as controlled by the micromachines 56 yields a titanium nitride deposition rate of approximately 5-10 Å per second.

To improve or better control the stochiometry of the TiN film, an ALD process may also be used. In an ALD process, TiCl₄ and NH₃ are sequentially introduced into and then purged from the chamber as described generally above. As with the non-ALD process, the chamber 50 is preferably held at pressure of approximately 5 torr and a temperature of approximately 600° C. TiCl₄ is first flowed into the chamber at a rate of approximately 400 seem with a TiCl₄ pulse time of approximately 75 milliseconds, followed by a TiCl₄ chamber purge lasting approximately 100 milliseconds. Following the TiCl₄ purge, NH₃ is introduced into chamber at a flow rate of 100 sccm with an NH₃ pulse time of 125 milliseconds, followed by an NH₃ purge time of 100 milliseconds. The cycle of introducing and purging TiCl₄ and then introducing and purging NH₃ yields a titanium nitride deposition rate of 0.3 to 1 Å per cycle. One skilled in the art will realize from this exemplary process flow that an ALD layer can be achieved with much greater speed than was possible in the prior art, because it is not necessary to purge the prior art conduit which fed the shower head. Instead, in a preferred embodiment, the only purging required is that performed by the chamber pump after each precursor iteration, which is much less time consuming, and hence improves manufacturing throughput.

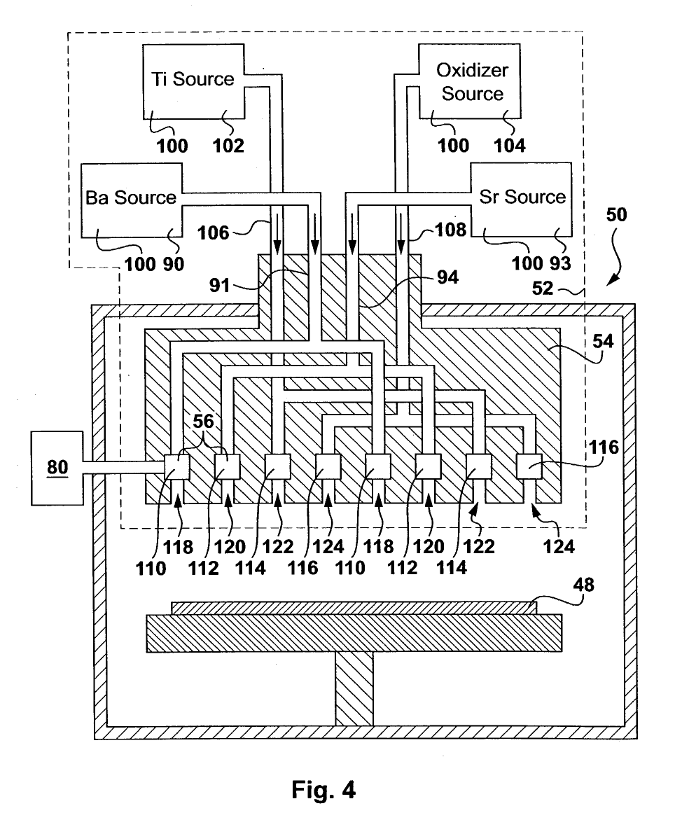

Another process which is benefited by the disclosed gas precursor delivery system is the deposition of BST oxides. As previously explained, it is difficult to control the stochiometry of BST oxides, and to improve their throughput. The disclosed system however, shown in FIG. 4, allows this film to be deposited with relative ease. As shown, there are four gas precursor sources 100 needed to deposit a BST oxide, a barium source 90 (such as Ba(thd)₂-tetraglyme) coupled to line 91, micromachines 110, and holes 118, a strontium source 93 (such as Sr(thd)₂-tetraglyme) coupled to line 94, micromachines 112 and holes 120, a titanium source 102 (such as Ti(OPri)₄) coupled to line 106, micromachines 114 and holes 122, and an oxidizing source 104 (such as oxidizing gases well known to those skilled in the art that may contain Argon as well as O₂ or N₂O) coupled to line 108, micromachines 116 and holes 124. But as is well understood by those skilled in the art other barium, strontium, titanium and oxidizer precursor gases at sources 100 may be employed.

In a preferred embodiment, these precursors are introduced into the chamber in series to create an ALD film. The chamber 50 is preferably held between 1 to 10 torr and at a temperature of between 500 to 650° C., although routine experimentation might be required to optimize these or other process parameters to achieve a particular film thickness or desired stochiometry. Each of the precursors, including the oxidizer, is introduced into the chamber at flow rates of 10-500 sccm for a time of 50 to 1000 ms, and is followed by a chamber purge of 50 to 1000 ms before the next precursor is introduced. The resultant BST oxide film, depending on the exact process parameters used, will run yield a deposition rate of approximately 0.3 to 1 Å per cycle.

This ALD process is easily modified using the disclosed shower head design. For example, the barium and titanium sources can be pulsed into the chamber at the same time, then purged. This can be followed by pulsing and purging the oxidizer. Thereafter, the strontium and titanium sources can be pulsed into the chamber at the same time, and then purged, followed again by pulsing and purging the oxidizer. Thereafter, the process repeats until the ALD film is fully grown.

In another ALD process, barium and titanium precursor gases are introduced and then purged at the same time, followed by the introduction and then purging of an oxidizer, followed by the introduction and then purging of strontium and titanium precursor gases, followed by the introduction and then purging of an oxidizer, etc.

As mentioned previously, a benefit of having a micromachine present at each hole in the shower head is that each micromachine can be independently controlled. Such precise control allows the distribution of vapors to be evenly distributed across the wafer surface. For example, it may be particularly useful in the deposition of ALD films to change or optimize the flow emitted from a single hole in the shower head. For example, processing analysis may show that the deposited film at a certain region of the wafer is not sufficiently thick. In this case, the pulse time of the micromachines present proximate to that region of the wafer could be left on longer than other micromachines that are used to pass the same vapor to different portions of the wafer. Additionally, the timing of the pulse, as well as its duration, may be varied to optimize the process, with some micromachines being engaged earlier, or later, than other like micromachines. This provides great flexibility to tailor the process of a given deposition, and to adjust the process to variations that might be inherently present in the deposition system, and which otherwise would not be amenable to adjustment. Moreover, individualized adjustment of the flow at each of the micromachines might provide other benefits as well. For example, incomplete vaporization from a given hole in the shower head can lead to particles which can adversely affect the operation of the circuits that are being processed. However, by adjusting the micromachines at the affected holes, this problem can potentially be eliminated, while still providing adequate and uniform vapor flows.

From the foregoing detailed description of specific embodiments of the invention, it should be apparent that an improved device and method for delivering gas precursors to a deposition chamber has been disclosed. Although specific embodiments of the invention have been disclosed herein in some detail, this has been done solely for the purposes of illustrating various aspects and features of the invention, and is not intended to be limiting with respect to the scope of the invention. For example, the deposition of titanium nitride or BST oxides have been disclosed merely as illustrative of a film that may benefit from the use of the disclosed gas precursor delivery system, but one skilled in the processing arts will recognize that any number of films could be similarly processed using the disclosed techniques, and that the disclosed techniques are not limited to the deposition of these disclosed films. Moreover, while the disclosed precursor delivery system has particular utility for ALD films, it may be employed with significant benefits to non-ALD films.

While the term “micromachines,” or more specifically “microvalves” or “micropumps” have been used to describe the flow regulators used in the disclosed gas delivery system, it should be understood that the qualifier “micro” has been used to denote that these devices are, relatively speaking, smaller than traditional pumps or valves, or other flow-regulating devices. However, it should not be understood that this disclosure is limited to the use of such relatively small devices, and instead might cover suitable flow-regulating devices of any size.

Additionally, it should be understood that while the disclosed micromachines are perceived as being a particularly useful way of implementing the disclosed gas delivery system, such micromachines are not strictly necessary in all embodiments of the invention. Thus, the source chemicals 69 in FIG. 2A, once vaporized if necessary, can be made to flow directly into lines 61 and 64 and out holes 57 without being blocked by micromachines. Optionally, a valve, pump, or flow controller 85 might be placed in the lines at a point before they branch into the smaller conduits that flow to the individual holes 57 to allow the entry of the source gases to the chamber 50 to be controlled to some degree. Because each hole is still dedicated to one of the lines 61 or 64, the uniform dispersion of the precursors gases into the chamber 50 can still be controlled to some degree, although perhaps not as accurately as when micromachines are used directly in the proximity of the holes 57.

“Source chemical,” as used herein, should include individual chemicals or mixtures of chemicals, be they liquids or gases.

What is claimed is:

1. A shower head for a deposition chamber, comprising:
a plurality of holes for distributing a source chemical to the deposition chamber; and
a flow regulator proximate to each of the holes for controlling the flow of the source chemical to the chamber, wherein each flow regulator is independently controllable.

2. The shower head of claim 1, wherein the flow regulators comprise a device selected from the group consisting of a valve, pump, or flow controller.

3. The shower head of claim 1, wherein the flow regulators are capable of vaporizing the source chemical.

4. The shower head of claim 1, further comprising a controller coupled to the flow regulators for controlling the flow of the source chemicals to the chamber.

5. The showed head of claim 1, wherein each flow regulator comprises a piezoelectric actuator.

6. A gas delivery system for a deposition chamber, comprising:
a line coupleable to a source chemical, wherein the line communicates with a plurality of holes in communication with the chamber; and
a flow regulator proximate to each of the holes, wherein the flow regulators are independently controllable for controlling the flow of the source chemical to the chamber.

7. The gas delivery system of claim 6, wherein the flow regulators comprises a device selected from the group consisting of a valve, pump, or flow controller.

8. The gas delivery system of claim 6, further comprising a shower head for housing the flow regulators and the line.

9. The gas delivery system of claim 6, wherein the holes are located in an area on the chamber, and wherein the holes are evenly distributed about the area.

10. The gas delivery system of claim 9, further comprising a shower head, and wherein the area is located on the shower head.

11. The gas delivery system of claim 6, wherein the holes are located in an area on the chamber, and wherein the holes are circularly symmetrically arranged about the area.

12. The gas delivery system of claim 11, further comprising a shower head, and wherein the area is located on the shower head.

13. The gas delivery system of claim 6, wherein the flow regulators are capable of vaporizing the source chemical.

14. The gas delivery system of claim 6, further comprising a controller coupled to the flow regulators for controlling the flow of the source chemical to the chamber.

15. A method for delivering a source chemical into a deposition chamber, comprising:
conveying the source chemical by a line to a plurality of flow regulators placed proximate to a plurality of holes in communication with the chamber; and
independently controlling the flow regulators to control the flow of the source chemical to the chamber.

16. The method of claim 15, wherein the flow regulators comprises a device selected from the group consisting of a valve, pump, or flow controller.

17. The method of claim 15, wherein the chamber includes a shower head for housing the flow regulators and the line.

18. The method of claim 15, wherein the holes are located in an area on the chamber, and wherein the holes are evenly distributed about the area.

19. The method of claim 18, further comprising a shower head, and wherein the area is located on the shower head.

20. The method of claim 15, wherein the holes are located in an area on the chamber, and wherein the holes are circularly symmetrically arranged about the area.

21. The method of claim 20, further comprising a shower head, and wherein the area is located on the shower head.

22. The method of claim 15, wherein the flow regulators vaporize the source chemical.

23. The method of claim 15, further comprising vaporizing the source chemical in the line.

24. The method of claim 15, further comprising controlling the flow of the source chemical in the line.

25. The method of claim 15, wherein independently controlling the flow regulators comprises activating the flow regulators for differing amounts of time.

26. The method of claim 15, wherein independently controlling the flow regulators comprises activating the flow regulators at different times.

27. The method of claim 15, wherein independently controlling the flow regulators comprises activation of piezoelectric actuators associated with each of the flow regulators.

28. A method for delivering a source chemical into a deposition chamber, comprising:
conveying the source chemical to a plurality of holes in communication with the chamber; and
independently controlling the flow of the source chemical to the chamber at each of the holes.

29. The method of claim 28, wherein the flow is controlled at each of the holes by a flow regulator at each hole.

30. The method of claim 29, wherein the flow regulators comprise a device selected from the group consisting of a valve, pump, or flow controller.

31. The method of claim 29, wherein the flow regulators vaporize the source chemical.

32. The method of claim 28, wherein the holes are located in an area on the chamber, and wherein the holes are evenly distributed about the area.

33. The method of claim 32, further comprising a shower head, and wherein the area is located on the shower head.

34. The method of claim 28, wherein the holes are located in an area on the chamber, and wherein the holes are circularly symmetrically arranged about the area.

35. The method of claim 34, further comprising a shower head, and wherein the area is located on the shower head.

36. The method of claim 28, further comprising vaporizing the source chemical in the line.

37. The method of claim 28, further comprising controlling the flow of the source chemical in the line.

38. The method of claim 28, wherein independently controlling the flow of the source chemical to the chamber at each of the holes comprises flowing the source chemical through the holes for differing amounts of time.

39. The method of claim 28, wherein independently controlling the flow of the source chemical to the chamber at each of the holes comprises flowing the source chemical through the holes at different times.

40. The method of claim 28, wherein independently controlling the flow of the source chemical to the chamber at each of the holes comprises activation of piezoelectric actuators associated with each of the holes.
